(19) United States
(12) Patent Application Publication
(10) Pub. No.: US 2021/0140819 A1
(43) Pub. Date: May 13, 2021

(54) TUNABLE SPECTRUM SENSING DEVICE, OUT-OF-PLANE MOTION MOTOR AND PRODUCING METHOD THEREOF

(71) Applicant: Innovative Interface Laboratory Corp., Hsinchu City (TW)

(72) Inventor: Yu-Wen Hsu, Hsinchu City (TW)

(21) Appl. No.: 17/090,041

(22) Filed: Nov. 5, 2020

Related U.S. Application Data
(60) Provisional application No. 62/931,926, filed on Nov. 7, 2019.

(51) Int. Cl. G01J 3/28; H02N 1/00; G01J 5/12

(52) U.S. Cl. CPC G01J 3/2803; H02N 1/008; G01J 2005/0077; G01J 5/12; G01J 3/2823

(57) ABSTRACT

The present invention provides a tunable spectrum sensing device. The tunable spectrum sensing device includes: a device body; an out-of-plane motion motor mounted on the device body and including: a base having a normal direction; and a single-axis actuator having a motion direction parallel to the normal direction, and including: a substrate with an electronic element; and an actuating end driven by the electronic element; a first glass mounted on and moved by the actuating end; and a second glass mounted on the device body. The out-of-plane motion motor can keep an object at a specific rotation angle, position the object at a specific out-of-plane displacement or be programmed for the object to perform a specific scan trajectory motion. The out-of-plane motion motor also has a large motion stroke, and thus, there is no need to use multiple tunable spectrum sensing devices to satisfy the spectral bandwidth requirement.

### CROSS-REFERENCE TO RELATED APPLICATION AND CLAIM OF PRIORITY

This application claims the benefit of U.S. Provisional Applications No. 62/931,926, filed on Nov. 7, 2019 in the United States Patent and Trademark Office, the disclosures of which are incorporated herein in their entirety by reference.

### FIELD OF THE INVENTION

The invention relates to an out-of-plane motion motor, and more particularly to a tunable spectrum sensing device including the out-of-plane motion motor.

### BACKGROUND OF THE INVENTION

Actuators can be classified by vibration state into the resonant type and the non-resonant type. The resonant type actuators have large rotational strokes and are driven by vertical comb structures. However, the resonant type actuators are not able to position an object at a certain angle and this is the reason why they always move in a route symmetric to a zero-bias position. In order to generate enough torque to rotate the object, the driving structures usually occupy several times the size of the object, and result in increased costs accordingly. Tunable spectrum sensing devices usually use the non-resonant type piezoelectric actuators with a very small stroke at the level of several hundred nanometers. Taking a tunable Fabry-Perot as an example, the small stroke actuator makes it difficult for the tunable Fabry-Perot to meet the spectral bandwidth required for many applications, and therefore multiple Fabry-Perots must be arranged in a group or in an array to satisfy the spectral bandwidth requirement.

### SUMMARY OF THE INVENTION

The present invention discloses a tunable spectrum sensing device including an out-of-plane motion motor that overcomes the drawback in prior art. The out-of-plane motion motor can keep an object at a specific rotation angle, position the object at a specific out-of-plane displacement or be programmed for the object to perform a specific scan trajectory motion. The out-of-plane motion motor also has a large motion stroke, and thus there is no need to use multiple tunable spectrum sensing devices to satisfy the spectral bandwidth requirement.

In accordance with an aspect of the present invention, a tunable spectrum sensing device is provided. The tunable spectrum sensing device includes: a device body; an out-of-plane motion motor mounted on the device body and including: a base having a normal direction; a sensor disposed on the base; and a single-axis actuator having a motion direction parallel to the normal direction, fixed on the base and including: a substrate with an electronic element; and an actuating end connected to the substrate and driven by the electronic element; a first glass mounted on and moved by the actuating end; and a second glass mounted on the device body.

In accordance with a further aspect of the present invention, an out-of-plane motion motor for carrying an object is provided. The out-of-plane motion motor includes: a base having a normal direction; and a single-axis motion motor having a motion direction parallel to the normal direction, fixed on the base and including a single-axis actuator carrying and moving the object.

In accordance with another aspect of the present invention, a method for producing an out-of-plane motion motor for carrying an object is provided. The method includes the following steps: providing a base having a normal direction; providing a single-axis motion motor having a motion direction parallel to the normal direction and including a single-axis actuator; and fixing the single-axis motion motor on the base so that the single-axis actuator carries and moves the object.

### BRIEF DESCRIPTION OF THE DRAWINGS

The details and advantages of the present invention will become more readily apparent to those ordinarily skilled in the art after reviewing the following detailed descriptions and accompanying drawings.

FIG. 1 shows a top view of an embodiment of an out-of-plane motion motor of the present invention.

FIG. 2 shows a sectional schematic diagram of a cut view of the out-of-plane motion motor along the section line A-A′ in FIG. 1.

FIG. 3 shows a top view of another embodiment of the out-of-plane motion motor of the present invention.

FIG. 4 shows a three dimensional diagram of the out-of-plane motion motor shown in FIG. 3.

FIG. 5 shows a schematic diagram of a single-axis actuator of the present invention.

FIG. 6 shows a partial schematic diagram of a single-axis actuator wafer of the present invention.

FIG. 7 shows an exploded view of an out-of-plane motion actuator of the present invention.

FIG. 8 shows a three dimensional diagram of the out-of-plane motion actuator of the present invention.

FIG. 9 shows a schematic diagram of an embodiment of a single-sided single-axis actuator of the present invention.

FIG. 10 shows a schematic diagram of an actuation of the single-sided single-axis actuator of the present invention.

FIG. 11 shows a schematic diagram of an embodiment of a double-sided single-axis actuator of the present invention.

FIG. 12 shows a schematic diagram of an actuation of the double-sided single-axis actuator of the present invention.

FIG. 13 shows a schematic diagram of another actuation of the double-sided single-axis actuator of the present invention.

FIG. 14 shows a schematic diagram of another actuation of the double-sided single-axis actuator of the present invention.

FIG. 15 shows a planar schematic diagram of a displacement magnifying mechanism of the present invention.

FIG. 16 is the schematic sectional view of an embodiment of the tunable spectrum sensing device of the present invention.

FIG. 17 is a schematic sectional view of the single-axis actuator shown in FIG. 5.

FIG. 18A shows an example in which the center of gravity of the first glass aligns the center of gravity of the single-axis actuator without the T-bar and the fulcrum hinge.

FIG. 18B shows an example in which the center of gravity of the first glass does not align the center of gravity of the single-axis actuator without the T-bar and the fulcrum hinge.

FIG. 18C shows an embodiment of the present invention with both the fulcrum hinge and the T-bar.

FIGS. 19A and 19B show the schematic top view of two additional embodiments of the fulcrum hinge of the present invention.

### DETAILED DESCRIPTION OF THE PREFERRED EMBODIMENT

The present invention will now be described more specifically with reference to the following embodiments. It is to be noted that the following descriptions of the preferred embodiments of this invention are presented herein for the purposes of illustration and description only; they are not intended to be exhaustive or to be limited to the precise form disclosed.

Please refer to FIG. 1 and FIG. 2, wherein FIG. 1 is a top view of an out-of-plane motion motor of an embodiment of the present invention, and FIG. 2 is a sectional schematic diagram of a cut view of the out-of-plane motion motor along the section line A-A′ in FIG. 1. FIG. 1 and FIG. 2 show that a first single-axis motion motor 7045-1 and a second single-axis motion motor 7045-2 configure on a base plate surface 852 of a base plate 851 of the out-of-plane motion motor 7040. As a mechanism that can produce a planar motion, a motion direction of an actuating end 855 of a single-axis actuator 854 is substantially parallel to a normal direction of the base plate surface 852. The normal direction for FIG. 1 is a direction that perpendicular to the drawing surface, and the normal direction for FIG. 2 is an upward direction. A carried object 5000′ is carried on the actuating end 855 of a single-axis actuator 854 in the single-axis motion motor 7045-1, wherein the carried object 5000′ can be a reflector, a reflecting mirror, a lens, a semi-reflecting mirror, etc. Because of the high-speed response performance of a micro-electromechanical system, the carried object 5000′ of the present invention can also be a vibrating membrane. According to the configuring positions of the first single-axis motion motor 7045-1 and the second single-axis motion motor 7045-2, the carried object 5000′ can not only be moved upwards and downwards in parallel, but also can be rolled. Therefore, the carried object 5000′ can have more displacement in the out-of-plane direction caused by the single-axis motion motors 7045-1 and 7045-2 of the present invention. In addition, because there is usually no need for other structures underneath the carried object 5000′ to support the carried object 5000′, a redundant space 852′ is formed between the carried object 5000′ and the base plate surface 852, where the electronic element 6009 can be configured therein to save the overall equipment space. In addition, in order to facilitate the handling of the out-of-plane motion motor 7040, a base plate frame 853 is formed on the periphery of the base plate 851 substantially parallel to the direction of the normal line of the base plate surface 852. That is, the periphery of the base plate 851 is thickened to facilitate the handling by a robotic arm (figure not shown).

Please refer to FIG. 3 and FIG. 4, wherein FIG. 3 is a top view of the out-of-plane motion motor according to another embodiment of the present invention, and FIG. 4 is a three dimensional diagram of the out-of-plane motion motor shown in FIG. 3. It can be seen in FIG. 3 and FIG. 4 that two single-axis motion motors 7045-1 and 7045-2 are no longer only configured on both sides on the base plate surface 852, but additional single-axis motion motors are further cooperatively configured on the four corners on the base plate surface 852, which include a first single-axis motion motor 7045-1, a second single-axis motion motor 7045-2, a third single-axis motion motor 7045-3 and a fourth single-axis motion motor 7045-4, and these four single-axis motion motors form the out-of-plane motion motor 7040 according to another embodiment of the present invention. Therefore, in the embodiment shown in FIG. 3 and FIG. 4, the carried object 5000′ can not only be moved upwards and downwards and parallel to the normal direction of the base plate surface 852, but also have pitching motion by synchronously controlling the first single-axis motion motor 7045-1 and the second single-axis motion motor 7045-2 and/or synchronously controlling the third single-axis motion motor 7045-3 and the fourth single-axis motion motor 7045-4, and thus the carried object 5000′ totally has three degrees-of-freedom. Specifically, the four single-axis motion motors can be controlled to generate different displacements respectively, so that the carried object 5000′ can have translational, rolled and pitched motions. The number and the configuring positions of the single-axis actuators in FIG. 3 and FIG. 4 are not absolute, and can be altered according to actual demands. For example, because three points can form a plane, in theory, only three single-axis actuators are needed to achieve three degrees-of-freedom movements, i.e. translation of up-and-down and rotations of roll and pitch.

Please refer to FIG. 5, which is a schematic diagram of a single-axis actuator according to one embodiment of the present invention. A detailed structure of the single-axis actuator 854 is showed in FIG. 5. The single-axis actuator 854 mainly includes a movable electrode structure 500 and fixed electrode structures including a first fixed electrode structure 300 and a second fixed electrode structure 610. The movable electrode structure 500 has a keel 510 and comb fingers 520 fixed on the keel 510, and the first fixed electrode structure 300 has comb fingers 320 fixed on a supporting arm 1200. A sensing capacitor 600 including the second fixed electrode structure 610 and the movable electrode structure 500 is formed for sensing a capacitance value therebetween, and a distance between the movable electrode structure 500 and the first fixed electrode structure 300 is obtained through the conversion of the measured capacitance value. The first fixed electrode structure 300 is indirectly fixed by a third anchor 803 through the supporting arm 1200, and the second fixed electrode structure 610 is fixed by a fourth anchor 804. The movable electrode structure 500 is indirectly fixed by a second anchor 802 through two constraining hinges 900 which can prevent the movement of the movable electrode structure 500 from exceeding the allowable range. An embodiment of the actuating end 855 is a T-bar 1100, wherein the T-bar 1100 is fixed on the movable electrode structure 500, and is indirectly fixed by a first anchor 801 through two main hinges 400. A first center point 450 is formed between the T-bar 1100 and the main hinges 400 at the two sides of the T-bar 1100. The main hinges 400 are used to carry the most weight of the T-bar 1100 and the weight of the movable electrode structure 500, and bear an elastic restoring force of returning the T-bar 1100 when the electrostatic force between the movable electrode structure 500 and the first fixed electrode structure 300 disappears. In order to avoid the T-bar 1100 and the carried object 5000′ from separating by a lateral force applied to the T-bar 1100 or the carried object 5000′, a fulcrum hinge 700 is configured on a vertical portion of the T-bar 1100. The fulcrum hinge 700 can deform laterally to absorb the aforementioned lateral force. In addition, in order to maintain a parallelism of a head portion of the T-bar 1100, i.e. the parallelism between the T-bar 1100 and the base plate surface 852, the fulcrum hinge 700 can be designed to be undeformable under forces applied in the normal direction (Y direction in FIG. 5) of the base plate surface 852.

Please refer to FIG. 6, which is a partial schematic diagram of an actuator wafer of the present invention. The actuator wafer 20000 includes a plurality of single-axis actuating structures. FIG. 6 shows a part of an actuator wafer 20000 containing one single-axis actuator structure 10000. After the single-axis actuator structure 10000 is cut from the actuator wafer 20000, the single-axis actuator 854 is obtained. The single-axis actuating structure 10000 of the micro-electromechanical system is manufactured using semiconductor process technology, which can form a plurality of the single-axis actuators on a piece of the actuator wafer 20000, and then the actuator wafer 20000 is cut into the plurality of the single-axis actuators. In order to avoid the trouble caused by process residues and debris, a cavity 200 is formed below the comb fingers 520 of the movable electrode structure 500 and the comb fingers 320 of the first fixed electrode structure 300 in the present invention, so that the residues and debris can be discharged from the cavity 200 or can be at least settled in the cavity 200 to keep away from each fingers. For the same reason, a third cavity 20500 is formed under the T-bar 1100 to facilitate the discharge of the residues and debris generated by the manufacturing process under the T-bar 1100.

Please refer to FIG. 7 and FIG. 8, wherein FIG. 7 is an exploded view of an out-of-plane motion actuator of the present invention, and FIG. 8 is a three dimensional diagram of the out-of-plane motion actuator of the present invention. FIG. 7 and FIG. 8 show that the single-axis actuator 854 formed by cutting from the single-axis actuating structure 10000 in FIG. 6 is configured on an actuator connection seat 6001′ to form the single-axis motion motor 7045. In FIGS. 5, 7 and 8, it can be seen that the single-axis actuator 854 includes a substrate 100, to which the actuating end 855, the first anchor 801, the second anchor 802, the third anchor 803 and the fourth anchor 804 are connected. A control chip 6008 can be further configured on the actuator connection seat 6001′ and adjacent to the single-axis actuating structure 10000 to control the single-axis actuating structure 10000 nearby. The actuator connection seat 6001′ is fixed on the base plate 6003 by clamps 6004. Contact pads 6006 of the actuator connection seat 6001′ are electrically connected to metal pads 6007 on the base plate surface 6005, causing the electronic signal to be transmitted to the control chip 6008 and each of the comb fingers 520, 320 through the contact pads 6006, the metal pads 6007 and the circuit in the actuator connection seat 6001′ (figure not shown) to form a complete route of the electronic signal for the out-of-plane motion actuator 6000. According to requirements, other electrical connection pads 6007′ can be further configured on the base plate surface 6005 to electrically connect to other electronic elements (figure not shown). The metal pads 6007 and the electrical connection pads 6007′ present, but are not limited to, one-to-one correspondence relationship. For the actuator connection seat 6001′, the metal pads 6007 or the electrical connection pads 6007′ can be used, that is, the position of the actuator connection seat 6001′ can be determined according to the actual demand, such as a size of the carried object 5000′.

Please refer to FIG. 9 and FIG. 10, wherein FIG. 9 is a schematic diagram of a motor having only one single-axis actuator (or called a single-sided single-axis-actuator motor) according to an embodiment of the present invention, and FIG. 10 is a schematic diagram of an actuation of the single-sided single-axis-actuator motor of the present invention. FIG. 9 and FIG. 10 show that one side of the single-sided single-axis-actuator motor 8000 is a fulcrum structure 7000, and the opposite side of the single-sided single-axis-actuator motor 8000 is the single-axis motion motor 7045 of the present invention. Therefore, the fulcrum structure 7000 and the single-axis motion motor 7045 are respectively located at the two sides, the left and the right sides or the front and the rear sides, of the carried object 5000′. Of course, the fulcrum structure 7000 and the single-axis motion motor 7045 can also be respectively located at the diagonal sides of the carried object 5000′. Only a slight rotation of the carried object 5000′ is allowed on the fulcrum structure 7000. The fulcrum structure 7000 usually has, but is not limited to, a structure such as fulcrum hinge 700 (as shown in FIG. 5) to absorb shear stress caused by improper external forces. When the single-axis motion motor 7045 moves upwards or downwards, the position of the carried object 5000′ connected thereto is also moved upwards or downwards along with the single-axis motion motor 7045. FIG. 10 shows the position of the carried object 5000′ connecting to the single-axis motion motor 7045 while the single-axis motion motor 7045 moves upwards to a top dead center (TDC) or downwards to a bottom dead center (BDC). Furthermore, in order to protect the carried object 5000′, a protective structure 5000″ mounted above the carried object 5000′ is provided in the present invention. The protective structure 5000″ is usually supported by a supporting wall 902 of an accommodating base 910. The out-of-plane motion motor 7040 (figure not shown) including the plurality of single-axis motion motors 7045 is configured on the accommodating bottom plate 901 of the accommodating base 910.

Please refer to FIG. 11, FIG. 12 and FIG. 13, wherein FIG. 11 is a schematic diagram of an embodiment of a two-sided single-axis-actuator motor of the present invention, FIG. 12 is a schematic diagram of an actuation of the two-sided single-axis-actuator motor of the present invention, and FIG. 13 is a schematic diagram of another actuation of the two-sided single-axis-actuator motor of the present invention. FIG. 11, FIG. 12 and FIG. 13 show that one side of the two-sided single-axis-actuator motor 9000 is the first single-axis motion motor 7045-1 of the present invention, and the opposite side of the two-sided single-axis-actuator motor 9000 is the second single-axis motion motor 7045-2 of the present invention. FIG. 12 shows the position of the two ends of the carried object 5000′ respectively connecting to the first single-axis motion motor 7045-1 and the second single-axis motion motor 7045-2 while the first single-axis motion motor 7045 moves up to its top dead center, and the second single-axis motion motor 7045-2 moves down to its bottom dead center at the same time. Contrary to FIG. 12, FIG. 13 shows the position of the two ends of the carried object 5000′ respectively connecting to the first single-axis motion motor 7045-1 and the second single-axis motion motor 7045-2 while the first single-axis motion motor 7045 moves down to its bottom dead center, and the second single-axis motion motor 7045-2 moves up to its top dead center at the same time. However, in the implementation state of some actuators, they can only move upwards or downwards, and then return to their original relatively low or relatively high positions. If the embodiments of FIG. 12 and FIG. 13 are understood as the actuator that can only move upwards, it can be understood in FIG. 12 that the second single-axis motion motor 7045-2 remains stationary, while the first single-axis motion motor 7045-1 moves upwards, for example, to its top dead center. In contrast, it can be understood in FIG. 13 that the first single-axis motion motor 7045-1 remains stationary, while the second single-axis motion motor 7045-2 moves upwards. Similarly, if the embodiments of FIG. 12 and FIG. 13 are understood as the actuator that can only move downwards, it can be understood in FIG. 12 that the first single-axis motion motor 7045-1 remains stationary, while the second single-axis motion motor 7045-2 moves downwards, for example, to its bottom dead center. In contrast, it can be understood in FIG. 13 that the second single-axis motion motor 7045-2 remains stationary, while the first single-axis motion motor 7045-1 moves downwards.

Please refer to FIG. 14, which is a schematic diagram of another actuation of the double-sided single-axis actuator of the present invention. When the single-axis actuator can only move upwards or downwards, the present invention can still achieve both translational and rolling movement according to the difference of the moving amplitude of the two actuators. Please see the two downward hollow arrows in FIG. 14, when the first single-axis motion motor 7045-1 and the second single-axis motion motor 7045-2 can only move downwards, the downward movement amount of the first single-axis motion motor 7045-1 is larger, and the downward movement amount of the second single-axis motion motor 7045-2 is smaller. Similarly, please see the two upward hollow arrows in FIG. 14, when the first single-axis motion motor 7045-1 and the second single-axis motion motor 7045-2 can only move upwards, the upward movement amount of the first single-axis motion motor 7045-1 is smaller, and the upward movement amount of the second single-axis motion motor 7045-2 is larger.

Please refer to FIG. 15, which is a planar schematic diagram of a displacement magnifying mechanism of the present invention. In order to increase the moving distance, a displacement magnifying mechanism 4000 can be used in the present invention. The displacement magnifying mechanism 4000 of the present invention includes a first lever L1 and a second lever L2, wherein an end of the first lever L1 is a first lever fulcrum L1f, and the other end of the first lever L1 connects to the second lever L2 through a second contact point L2c. The point of application of the out-of-plane motion actuator 6000 is at a first contact point L1c. Because the first contact point L1c is located between the first lever fulcrum L1f and the second contact point L2c, the moving amplitude of the second contact point L2c is larger than that of the first contact point L1c, when the out-of-plane motion actuator 6000 moves. Similarly, because the second contact point L2c is located between a second lever fulcrum L2f and a carrying point L2m, the moving amplitude of the carrying point L2m is larger than that of the second contact point L2c, when the second contact point L2c moves. Therefore, the displacement of the out-of-plane motion actuator 6000 can be magnified, so that the displacement of the carried object 5000′ is larger than that of the out-of-plane motion actuator 6000. If a more significant amplification effect is desired, a first distance a is smaller than a second distance b, and a third distance c is smaller than a fourth distance d, wherein the first distance a is a distance between the first contact point L1c and the first lever fulcrum L1f, the second distance b is a vertical distance between the first contact point L1c and the second contact point L2c, the third distance c is a distance between the second contact point L2c and the second lever fulcrum L2f, and the fourth distance d is a vertical distance between the second contact point L2c and the carrying point L2m. Accordingly, although the piezoelectric material in the prior art uses a displacement amplifying mechanism to enlarge its moving distance, the original displacement distance of the actuator of the present invention is much greater than that of the piezoelectric material, and thus the overall displacement distance achieved by the present invention is still far greater than the displacement distance of the piezoelectric material after being amplified by the displacement amplifying mechanism.

An embodiment of the application of the out-of-plane motion motor is that the out-of-plane motion motor is applied in a tunable spectrum sensing device 50000. Please refer to FIG. 16, which is the schematic sectional view of an embodiment of the tunable spectrum sensing device 50000 of the present invention. For the tunable spectrum sensing device 50000, the out-of-plane motion motor 54000 carries a first glass 51000. The first glass 51000 may be glass with an anti-reflection layer. The tunable spectrum sensing device 50000 also includes a device body 52000, the out-of-plane motion motor 54000 mounted on the device body 52000 and a second glass 53000 also mounted on the device body 52000. The second glass 53000 may also be a glass with an anti-reflection layer. The first glass 51000 and the second glass 53000 form a tunable spectral filter. A predetermined size of the gap between the first glass 51000 and the second glass 53000 is chosen based on application needs. The first glass 51000 and the second glass 53000 may be glass chips. The out-of-plane motion motor 54000 includes a base 54100, a sensor 54200 and a single-axis motion motor 54300. The base 54100 corresponds to the base plate 851 in FIG. 1. In FIG. 1, the base plate 851 has a base plate surface 852 and a base plate frame 853 disposed on the periphery of the base plate surface 852. In some embodiments of the tunable spectrum sensing device 50000, the base 54100 may not have the base plate frame. On the other hand, the device body 52000 usually includes a base plate with a frame disposed on the periphery of the surface of the base plate. The second glass 53000 is disposed on the frame, so that the second glass 53000 and the device body 52000 form a closed space. The vacuum level of the closed space can be controlled. The base 54100 has a normal direction, which is parallel to the surface of the paper in FIG. 16. For the tunable spectrum sensing device 50000, the sensor 54200 of the out-of-plane motion motor 54000 is disposed on the base 54100. The sensor 54200 is responsible for converting the light signal to electrical signal, and can be a thermopile sensor, a photodetector, a thermopile sensor array, a photodetector array, a complementary metal-oxide-semiconductor (CMOS) image sensor, a CMOS image sensor with an actuator, a thermal image sensor, a thermal image sensor with an actuator or a combination thereof. The sensor 54200 may be a chip.

In general, the out-of-plane motion motor 54000 includes at least one single-axis motion motor 54300. Each of the at least one single-axis motion motor 54300 includes a single-axis actuator 854. FIG. 5 shows an embodiment of the single-axis actuator 854, and FIG. 17 is a schematic sectional view of the single-axis actuator 854 along the section line C-C′ in FIG. 5. Please refer to FIGS. 5, 7 and 16-17, the single-axis actuator 854 includes a substrate 100 and the actuating end 855 connected to the substrate 100, as shown in FIG. 7. The first glass 51000 is mounted on and moved by the actuating end 855. In mounting the first glass 51000, the first glass 51000 is well aligned and fixed to the actuating end 855. It is seen from FIG. 17 that the substrate 100 of the single-axis actuator 854 has the cavity 200 and an electronic element 110. The electronic element 110 disposed on the substrate 100 represents the integration of all the motion control electronic components and circuits on the substrate 100. Therefore, the actuating end 855 in FIG. 16 may be driven by the electronic element 110 for carrying and moving the first glass 51000. The substrate 100 of the single-axis actuator 854 has a front surface 120 and a rear surface 130, and the cavity 200 penetrates through the front surface 120 and the rear surface 130 in the Z-direction as defined in FIG. 5. As shown in FIG. 5, the single-axis actuator 854 may have a comb type driving capacitor including a fixed electrode structure 300 fixed on the substrate 100 (shown in FIG. 17) and a movable electrode structure 500 connected to the main hinge 400. The size of the cavity 200 has to be sufficiently large to completely remove the residual materials from processing; a square with side length slightly more than 10 microns would be sufficiently large. To put it another way, if one looks upwards from the cavity 200 on the rear surface 130 and sees any comb finger, then the cavity 200 is sufficiently large. Without the cavity 200, the comb fingers 320, 520 in FIG. 5 have to be sparsely arranged to remove the residual materials. But when the comb fingers 320, 520 are sparsely arranged, the efficiency of electrical-to-mechanical energy conversion is low. In other words, the voltage applied between the first fixed electrode structure 300 and the movable electrode structure 500 has to be high. Hence, the cavity 200 allows the removal of residual process contaminants and the improvement of the efficiency of electrical-to-mechanical energy conversion. From another point of view, the cavity 200 allows the single-axis actuator 854 to have a larger motion stroke compared to the single-axis actuators in prior art for the same voltage applied. An embodiment of the actuating end 855 in FIG. 16 is the T-bar 1100 in FIG. 5. In the embodiment shown in FIGS. 5, 7 and 17, the T-bar 1100 is connected to the substrate 100 through the main hinge 400 and the fulcrum hinge 700.

The fulcrum hinge 700 is designed to prevent the first glass 51000 from peeling off from the T-bar 1100 when there is a shear force at a boundary surface between the first glass 51000 and the T-bar 1100. In general, the actuating end 855 carries and moves an object, and the fulcrum hinge 700 prevents the object from peeling off from the T-bar 1100. FIG. 18A shows an example in which the center of gravity of the first glass 51000 aligns the center of gravity of the single-axis actuator without the T-bar and the fulcrum hinge. In comparison, FIG. 18B shows an example in which the center of gravity of the first glass 51000 does not align the center of gravity of the single-axis actuator without the T-bar and the fulcrum hinge. In FIG. 18B, the stress concentrates on the circled area, and thus, a torque is produced. FIG. 18C shows an embodiment of the present invention with both the fulcrum hinge 700 and the T-bar 1100 to avoid the problem arising from FIG. 18B. The fulcrum hinge 700 has low stiffness in the X-direction shown in FIG. 5, but high stiffness in the Y-direction and Z-direction. In other words, the stiffness in the Y-direction k_{Y} is much greater than the stiffness in the X-direction k_{X}, i.e. k_{Y}>>k_{X}, and the stiffness in the Z-direction k_{Z} is also much greater than the stiffness in the X-direction k_{X}, i.e. k_{Z}>>k_{X}. High stiffness in the Y-direction is necessary to avoid the decrease of displacement in the Y-direction. One skilled in the art can design a variety of fulcrum hinges to meet the requirements. FIGS. 19A and 19B show the schematic top view of two embodiments of the fulcrum hinge in addition to the fulcrum hinge 700 shown in FIG. 5 or 18C. For the case without the fulcrum hinge 700, an external X-directional (as defined in FIG. 5) force applied to the object carried by the actuating end may generate a shear force and a moment at the boundary surface between the object and the T-bar 1100. The large shear force and/or the moment may cause the object to peel off from the surface of T-bar 1100. For the case with the fulcrum hinge 700, the external X-directional force applied to the object may lead to a deformation of the fulcrum hinge 700 to reduce the shear force and the moment at the boundary surface between the object and the T-bar 1100. In some circumstances, the fulcrum hinge 700 can be omitted if the shear force is negligible.

The single-axis actuator 854 allows the making of the out-of-plane motion motor 54000 with a large motion stroke, the robustness of impact, the easy removal of residual process contaminants, an improvement of the efficiency of electrical-to-mechanical energy conversion and the off-axis motion decoupling of movable comb structure.

The basic structure of the out-of-plane motion motor 54000 of the tunable spectrum sensing device 50000 is shown in FIGS. 7 and 8. The base 54100 in FIG. 16 corresponds to the base plate 6003 in FIGS. 7 and 8. In FIGS. 7 and 8, the single-axis motion motor 7045, with the single-axis actuator 854 parallelly fixed on the actuator connection seat 6001′ of the single-axis motion motor 7045, is fixed on the base plate 6003 in such a way that the single-axis actuator 854 has a motion direction parallel to the normal direction of the base plate 6003. If the out-of-plane motion motor 54000 includes more than one single-axis motion motor 54300 fixed on the base 54100, each of the single-axis motion motors 54300 may include a single-axis actuator 854 moving parallel to the normal direction of the base 54100. Each of the single-axis motion motors 54300 has contact pads 6006 (shown in FIGS. 7 and 8) and there are corresponding metal pads 6007 and electrical connection pads 6007′ (shown in FIGS. 7 and 8) on the base 54100. The single-axis motion motors 54300 can be fixed on the base 54100 by welding contact pads 6006 with corresponding metal pads 6007 on the base 54100. The clamps 6004 shown in FIGS. 7 and 8 may be omitted in some embodiments.

In the embodiment of the tunable spectrum sensing device 50000 shown in FIG. 16, there are two single-axis motion motors 54300. As the motion displacement of each of the single-axis motion motors 54300 is independently changed, the first glass 51000 can be driven to move in the out-of-plane direction or rotate around an in-plane direction. In other words, the first glass 51000 can perform single-axis rotational and out-of-plane translational movements. The first glass 51000 can also be kept at a specific rotation angle, positioned at a specific out-of-plane displacement or programmed to perform a specific scan trajectory motion. When the gap between the first glass 51000 and the second glass 53000 is changed by the two single-axis motion motors 54300, the incident light wavelength received by the sensor 54200 is changed. As the sensor 54200 is a linear array type sensor such as thermopile linear array, the tunable spectrum sensing device 50000 is able to provide each pixel in the linear array with light of different wavelength.

A single single-axis motion motor 54300 can also be used in the tunable spectrum sensing device 50000. The design may be similar to that depicted in FIG. 9, in which one single-axis motion motors 54300 is replaced by a fixed support allowing a slight rotation of the first glass 51000 around an in-plane axis defined by the fixed support. There can be other designs for a tunable spectrum sensing device 50000 using a single single-axis motion motor 54300, including different positions and orientations of the single single-axis motion motor 54300. One skilled in the art can design a variety of such tunable spectrum sensing devices to meet the application needs. In a tunable spectrum sensing device 50000 using a single single-axis motion motor 54300, the sensor 54200 may be a linear array type sensor.

In another embodiment, a similar device with a single single-axis motion motor can also be used in fluid flow control. The fluid flow control device using a single single-axis motion motor may function like a fan. The object carried by the actuating end in the fluid flow control device may be a plate made of, e.g., silicon, glass or metal. The present invention provides the out-of-plane motion motor 54000 with a single-axis motion motor 54300, and one skilled in the art can design the rest of the fluid flow control device to meet the application needs.

Three single-axis motion motors 54300 can also be used in the tunable spectrum sensing device 50000 to achieve three-degree-of-freedom movements as mentioned above. Another embodiment with three degrees of freedom utilizes the basic structure shown in FIGS. 3 and 4. There are four single-axis motion motors 54300 and the schematic diagonal sectional view of the tunable spectrum sensing device 50000 looks similar to FIG. 16. As the motion displacement of each of the single-axis motion motors 54300 is independently changed, the first glass 51000 can perform dual-axis rotational and out-of-plane translational movements. As the sensor 54200 is an array type sensor such as thermopile array, this single axis translational and dual axis rotational motion tunable spectrum sensing device 50000 is able to provide each pixel in the array with light of different wavelength.

### Embodiments

1. A tunable spectrum sensing device, including: a device body; an out-of-plane motion motor mounted on the device body and including: a base having a normal direction; a sensor disposed on the base; and a single-axis actuator having a motion direction parallel to the normal direction, fixed on the base and including: a substrate with an electronic element; and an actuating end connected to the substrate and driven by the electronic element; a first glass mounted on and moved by the actuating end; and a second glass mounted on the device body.
2. The tunable spectrum sensing device according to Embodiment 1, wherein the substrate of the single-axis actuator has a front surface and a rear surface, and a cavity penetrates through the front and the rear surfaces.
3. The tunable spectrum sensing device according to Embodiment 1 or 2, wherein the out-of-plane motion motor further includes a second single-axis actuator having a motion direction parallel to the normal direction.
4. The tunable spectrum sensing device according to any one of Embodiments 1-3, wherein the out-of-plane motion motor further includes a second, a third and a fourth single-axis actuators each having a motion direction parallel to the normal direction.
5. The tunable spectrum sensing device according to any one of Embodiments 1-4, wherein the first glass and the second glass are glass chips.
6. The tunable spectrum sensing device according to any one of Embodiments 1-5, wherein the sensor is one selected from a group consisting of a thermopile sensor, a photodetector, a thermopile sensor array, a photodetector array, a CMOS image sensor, a CMOS image sensor with an actuator, a thermal image sensor, a thermal image sensor with an actuator and a combination thereof.
7. The tunable spectrum sensing device according to any one of Embodiments 1-6, wherein the actuating end is a T-bar.
8. The tunable spectrum sensing device according to any one of Embodiments 1-7, wherein the single-axis actuator further includes a main hinge and a fulcrum hinge, and the T-bar is connected to the substrate through the main hinge and the fulcrum hinge.
9. The tunable spectrum sensing device according to any one of Embodiments 1-8, wherein the fulcrum hinge is designed to prevent the first glass from peeling off from the T-bar when there is a shear force at a boundary surface between the first glass and the T-bar.
10. An out-of-plane motion motor for carrying an object, including: a base having a normal direction; and a single-axis motion motor having a motion direction parallel to the normal direction, fixed on the base and including a single-axis actuator carrying and moving the object.
11. The out-of-plane motion motor according to Embodiment 10, further including a second single-axis motion motor.
12. The out-of-plane motion motor according to Embodiment 10 or 11, further including a second, a third and a fourth single-axis motion motors.
13. The out-of-plane motion motor according to any one of Embodiments 10-12, wherein the single-axis actuator has a substrate with an electronic element.
14. The out-of-plane motion motor according to any one of Embodiments 10-13, wherein the single-axis actuator further has an actuating end connected to the substrate and driven by the electronic element for carrying and moving the object.
15. The out-of-plane motion motor according to any one of Embodiments 10-14, wherein the substrate of the single-axis actuator has a front surface and a rear surface, and a cavity penetrates through the front and the rear surfaces.
16. The out-of-plane motion motor according to any one of Embodiments 10-15, wherein the actuating end is a T-bar.
17. The out-of-plane motion motor according to any one of Embodiments 10-16, wherein the single-axis actuator further has a main hinge and a fulcrum hinge, and the T-bar is connected to the substrate through the main hinge and the fulcrum hinge.
18. The out-of-plane motion motor according to any one of Embodiments 10-17, wherein the fulcrum hinge is designed to prevent the object from peeling off from the T-bar when there is a shear force at a boundary surface between the object and the T-bar.
19. The out-of-plane motion motor according to any one of Embodiments 10-18, wherein the single-axis actuator further has a comb type driving capacitor including a fixed electrode structure fixed on the substrate and a movable electrode structure connected to the main hinge.
20. A method for producing an out-of-plane motion motor for carrying an object, including the following steps: providing a base having a normal direction; providing a single-axis motion motor having a motion direction parallel to the normal direction and including a single-axis actuator; and fixing the single-axis motion motor on the base so that the single-axis actuator carries and moves the object.

The out-of-plane motion motor provided by the present invention can keep an object at a specific rotation angle, position the object at a specific out-of-plane displacement or be programmed for the object to perform a specific scan trajectory motion. The out-of-plane motion motor also includes a single-axis actuator which allows the out-of-plane linear motion motor to have a large motion stroke. A single tunable spectrum sensing device including the out-of-plane motion motor can satisfy the spectral bandwidth requirement. Therefore, multiple tunable spectrum sensing devices are not needed.

It is contemplated that modifications and combinations will readily occur to those skilled in the art, and these modifications and combinations are within the scope of this invention.

What is claimed is:

1. A tunable spectrum sensing device, comprising:
a device body;
an out-of-plane motion motor mounted on the device body and including:
a base having a normal direction;
a sensor disposed on the base; and
a single-axis actuator having a motion direction parallel to the normal direction, fixed on the base and including:
a substrate with an electronic element; and
an actuating end connected to the substrate and driven by the electronic element;
a first glass mounted on and moved by the actuating end; and
a second glass mounted on the device body.

2. The tunable spectrum sensing device as claimed in claim 1, wherein the substrate of the single-axis actuator has a front surface and a rear surface, and a cavity penetrates through the front and the rear surfaces.

3. The tunable spectrum sensing device as claimed in claim 1, wherein the out-of-plane motion motor further includes a second single-axis actuator having a motion direction parallel to the normal direction.

4. The tunable spectrum sensing device as claimed in claim 1, wherein the out-of-plane motion motor further includes a second, a third and a fourth single-axis actuators each having a motion direction parallel to the normal direction.

5. The tunable spectrum sensing device as claimed in claim 1, wherein the first glass and the second glass are glass chips.

6. The tunable spectrum sensing device as claimed in claim 1, wherein the sensor is one selected from a group consisting of a thermopile sensor, a photodetector, a thermopile sensor array, a photodetector array, a CMOS image sensor, a CMOS image sensor with an actuator, a thermal image sensor, a thermal image sensor with an actuator and a combination thereof.

7. The tunable spectrum sensing device as claimed in claim 1, wherein the actuating end is a T-bar.

8. The tunable spectrum sensing device as claimed in claim 7, wherein the single-axis actuator further includes a main hinge and a fulcrum hinge, and the T-bar is connected to the substrate through the main hinge and the fulcrum hinge.

9. The tunable spectrum sensing device as claimed in claim 8, wherein the fulcrum hinge is designed to prevent the first glass from peeling off from the T-bar when there is a shear force at a boundary surface between the first glass and the T-bar.

10. An out-of-plane motion motor for carrying an object, comprising:
a base having a normal direction; and
a single-axis motion motor having a motion direction parallel to the normal direction, fixed on the base and including a single-axis actuator carrying and moving the object.

11. The out-of-plane motion motor as claimed in claim 10, further comprising a second single-axis motion motor.

12. The out-of-plane motion motor as claimed in claim 10, further comprising a second, a third and a fourth single-axis motion motors.

13. The out-of-plane motion motor as claimed in claim 10, wherein the single-axis actuator has a substrate with an electronic element.

14. The out-of-plane motion motor as claimed in claim 13, wherein the single-axis actuator further has an actuating end connected to the substrate and driven by the electronic element for carrying and moving the object.

15. The out-of-plane motion motor as claimed in claim 13, wherein the substrate of the single-axis actuator has a front surface and a rear surface, and a cavity penetrates through the front and the rear surfaces.

16. The out-of-plane motion motor as claimed in claim 14, wherein the actuating end is a T-bar.

17. The out-of-plane motion motor as claimed in claim 16, wherein the single-axis actuator further has a main hinge and a fulcrum hinge, and the T-bar is connected to the substrate through the main hinge and the fulcrum hinge.

18. The out-of-plane motion motor as claimed in claim 17, wherein the fulcrum hinge is designed to prevent the object from peeling off from the T-bar when there is a shear force at a boundary surface between the object and the T-bar.

19. The out-of-plane motion motor as claimed in claim 17, wherein the single-axis actuator further has a comb type driving capacitor including a fixed electrode structure fixed on the substrate and a movable electrode structure connected to the main hinge.

20. A method for producing an out-of-plane motion motor for carrying an object, comprising the following steps:
providing a base having a normal direction;
providing a single-axis motion motor having a motion direction parallel to the normal direction and including a single-axis actuator; and
fixing the single-axis motion motor on the base so that the single-axis actuator carries and moves the object.
